(19) United States
(12) Patent Application Publication
(10) Pub. No.: US 2014/0327841 A1
(43) Pub. Date: Nov. 6, 2014

(54) TOUCH SCREEN PANEL AND DISPLAY INCLUDING THE SAME

(71) Applicant: Electronics and Telecommunications Research Institute, Daejeon (KR)

(72) Inventors: Jaeheon SHIN, Daejeon (KR); Woo-Seok CHEONG, Daejeon (KR); Kyung Hyun KIM, Daejeon (KR); Rae-Man PARK, Daejeon (KR); Chan Hwa HONG, Jeollanam-do (KR)

(73) Assignee: Electronics and Telecommunications Research Institute, Daejeon (KR)

(21) Appl. No.: 14/176,694

(22) Filed: Feb. 10, 2014

(30) Foreign Application Priority Data
May 6, 2013 (KR) 10-2013-0050729

(51) Int. Cl. G06F 1/16; H01L 27/32; G02F 1/1333

(52) U.S. Cl. CPC G06F 1/169; G02F 1/13338; H01L 27/323; G06F 1/1643
USPC 349/12

(57) ABSTRACT

Provided is a touch screen panel. The touch screen panel according to an embodiment of the inventive concept includes a transparent substrate including a first region and a second region, a buffer layer disposed on the first region and second region, the buffer layer having a first transmittances, and a transparent indium tin oxide (ITO) electrode disposed on the buffer layer of the second region, the transparent ITO electrode and the buffer layer on the second region having a second transmittance, wherein a thickness of the transparent ITO electrode is 100 nm to 500 nm, and a difference between the first transmittance and the second transmittance is less than 1.5%.

### CROSS-REFERENCE TO RELATED APPLICATIONS

This U.S. non-provisional patent application claims priority under 35 U.S.C. §119 of Korean Patent Application No. 10-2013-0050729, filed on May 6, 2013, the entire contents of which are hereby incorporated by reference.

### BACKGROUND

The present invention disclosed herein relates to touch screen panels and displays including the same, and more particularly, to large-area touch screen panels having an improved transmittance and displays including the same.

Recently, computers and portable communication terminals have been universalized, and touch screens are being widely used as a means for inputting data as electronic devices. Touch screens may be classified into resistive type, capacitive type, surface acoustic wave type, and infrared type.

The resistive type touch screen is a device in which when a substrate is touched by using a finger or pen, an electrical signal is generated as transparent electrodes of upper and lower substrates are in contact with each other and data are input by identifying a position from the generated electrical signal. The resistive touch screen may be inexpensive and may be advantageous in miniaturization due to high optical transmittance, multi-touch, and fast response speed. Thus, the resistive type touch screens are mainly used in personal digital assistants (PDAs), portable media players (PMPs), navigations, and headsets.

The surface acoustic wave (SAW) type touch screen uses a technique of detecting a decrease in the magnitude of a surface acoustic wave when the emitted surface acoustic wave encounters an obstacle. Since the SAW type touch screens have advantages of high optical transmittance as well as high accuracy and sharpness, the SAW type touch screens are used in automated information terminals that are installed at external locations.

In the capacitive type touch screen, when a finger touches a substrate including a transparent electrode and is in contact with a conductor, a predetermined capacitance is generated in an insulating layer due to the static electricity generated from the finger. When a signal is transmitted through a portion in which the capacitance is generated, a position may be identified by calculating the intensity of the signal.

In particular, the capacitive type touch screen can realize multi touching based on sensitive touching. Therefore, the capacitive type touch screens may be suitable for large-sized and thin displays in which the sensitive touching is possible. An index-matched indium tin oxide (ITO) thin film structure may be used in order to realize the capacitive type touch screens. Index matching means a case where almost no difference of reflectivity between a portion with ITO interconnections and a portion without ITO interconnections is.

Typical knowledge until now is that a thickness of ITO may be required to about 40 nm or less in order to satisfy the above optical characteristics. As a result, the reality is that the capacitive type touch screens with multi-touch are limited to mobile devices having a display size of 15 inches or less. Thus, techniques, such as metal mesh and hybrid metal electrode (OMO), have discussed in order to realize a large-sized touch screen panel having a size of 20 inches or more. However, the above techniques may have limitations such as moire patterns and spectral inhomogeneity.

### SUMMARY

The present invention provides a touch screen panel having improved transmittance and index matching, and a display including the same.

The object of the present invention is not limited to the aforesaid, but other objects not described herein will be clearly understood by those skilled in the art from descriptions below.

Embodiments of the inventive concept provide touch screen panels including: a transparent substrate including a first region and a second region; a buffer layer disposed on the first region and second region, the buffer layer having a first transmittances; and a transparent indium tin oxide (ITO) electrode disposed on the buffer layer of the second region, the transparent ITO electrode and the buffer layer on the second region having a second transmittance, wherein a thickness of the transparent ITO electrode is 100 nm to 500 nm, and a difference between the first transmittance and the second transmittance is less than 1.5%.

In some embodiments, the first transmittance may be 85% or more.

In other embodiments, the buffer layer may include a high refractive index buffer layer on the substrate and a low refractive index buffer layer on the high refractive index buffer layer.

In still other embodiments, the high refractive index buffer layer may include Al₂O₃, MgO, SiNₓ, ZnO, HfO₂, ZnS, TiO₂, Nb₂O₅, Ta₂O₅, SrTiO₃, or CeO₂.

In even other embodiments, a thickness of the high refractive index buffer layer may be in a range of 3 nm to 30 nm.

In yet other embodiments, the low refractive index buffer layer may include SiO₂, SiOC, SiON, NaO₂, LaO₂, YtO₂, MgF₂, NaF, LiF, CaF₂, AlF₃, polymethyl methacrylate (PMMA), polyethylene, polypropylene, or polycarbonate.

In further embodiments, a thickness of the low refractive index buffer layer may be 10 nm to 60 nm.

In still further embodiments, the transparent electrode may include X-axis electrodes which include X-axis electrode cells aligned in a first direction and X-axis connection electrodes connecting the X-axis electrode cells, and Y-axis electrode cells which are spaced apart from the X-axis electrodes and are disposed adjacent to the X-axis connection electrodes in a Y-axis direction.

In even further embodiments, the touch screen panel may further include insulation patterns which cover the X-axis connection electrodes disposed between the Y-axis electrode cells, and bridge electrodes which are disposed on the insulation patterns and connect the Y-axis electrode cells.

In other embodiments of the inventive concept, displays include: a touch panel; an adhesive layer on the touch panel; and a display panel disposed on the adhesive layer, wherein the touch panel includes a transparent substrate including a first region and a second region; a buffer layer disposed on the first region and second region, the buffer layer having a first transmittances; and a transparent indium tin oxide (ITO) electrode disposed on the buffer layer of the second region, the transparent ITO electrode and the buffer layer on the second region having a second transmittance. A thickness of the transparent ITO electrode may be 100 nm to 500 nm, and a difference between the first transmittance and the second transmittance may be less than 1.5%.

In some embodiments, the adhesive layer may be an optically clear adhesive (OCA) film including a polymer.

In other embodiments, the display panel may include a liquid crystal panel or an organic light-emitting panel.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a plan view illustrating a touch screen panel according to an embodiment of the inventive concept;

FIGS. 2A through 2C are cross-sectional views taken along lines I-I′, II-II′, and III-III′ of FIG. 1 in a touch screen panel according to another embodiment of the inventive concept;

FIG. 3 is a graph illustrating the results of index matching of a touch screen panel according to a thickness of an indium tin oxide (ITO) layer in the touch screen panel including an optically transparent adhesive layer according to an embodiment of the inventive concept; and

FIGS. 4 and 5 are graphs illustrating transmittances when the thicknesses of the ITO layer are respectively about 120 nm and about 395 nm in the touch screen panel including an optically transparent adhesive layer according to the embodiment of the inventive concept.

### DETAILED DESCRIPTION OF THE EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals denote like elements throughout the specification.

In the following description, the technical terms are used only for explaining specific embodiments while not limiting the present invention. The terms of a singular form may include plural forms unless referred to the contrary. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be construed as limited to the scope of the present invention.

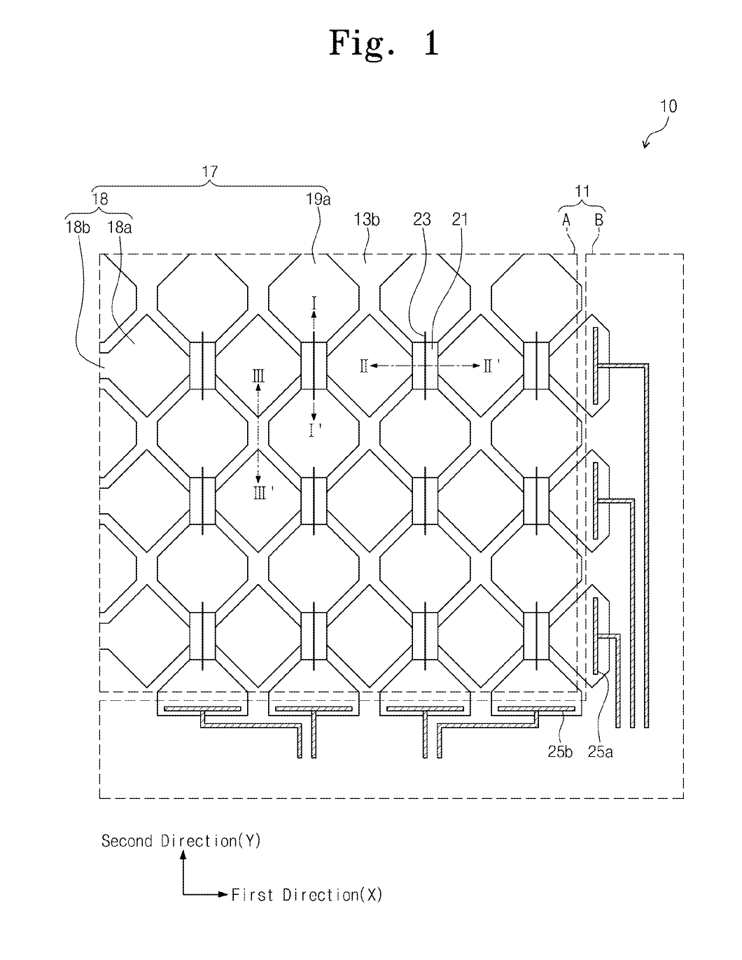

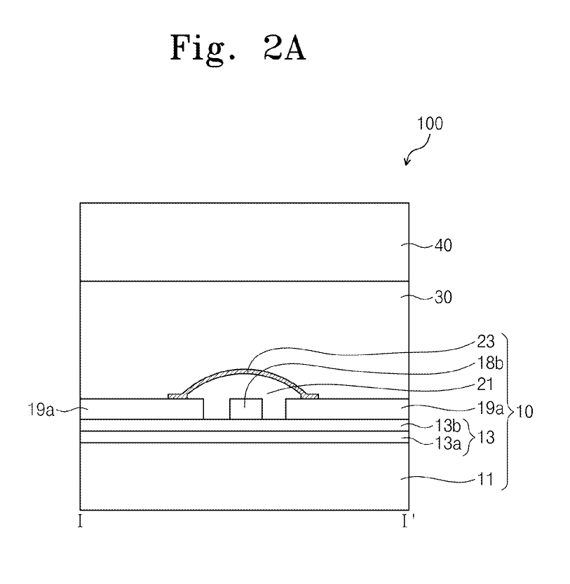

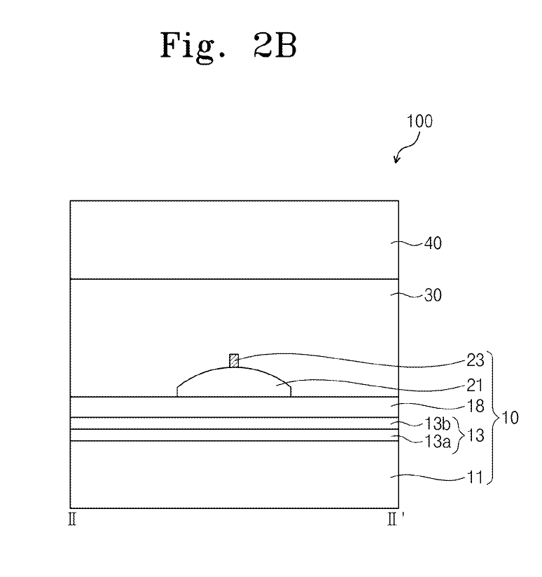

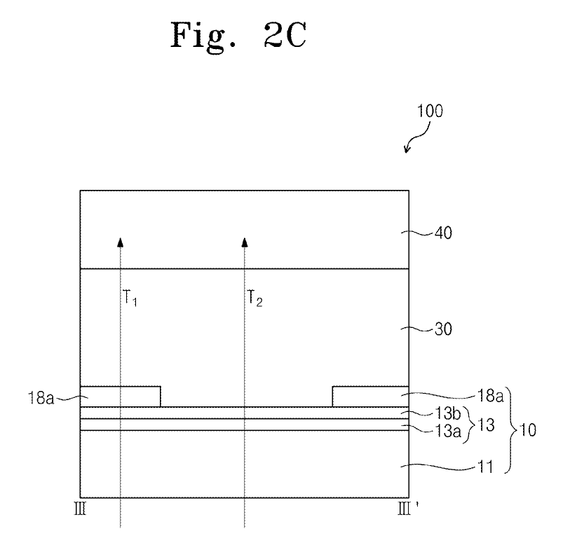

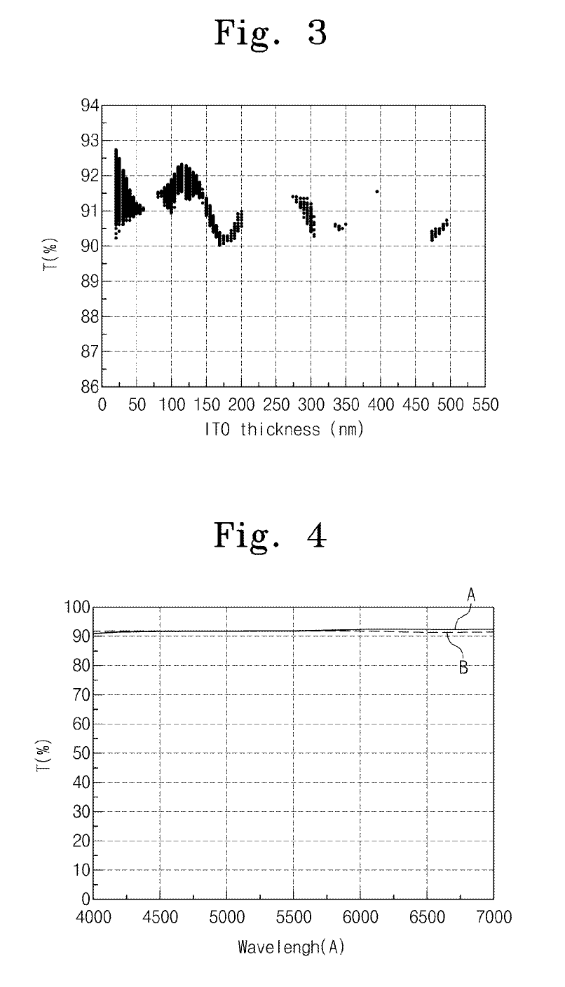

FIG. 1 is a plan view illustrating a touch screen panel according to an embodiment of the inventive concept. FIGS. 2A through 2C are cross-sectional views taken along lines I-I′, II-II′, and III-III′ of FIG. 1 in a touch screen panel according to another embodiment of the inventive concept. FIG. 3 is a graph illustrating the results of index matching of a touch screen panel according to a thickness of a transparent electrode in an embodiment of the inventive concept.

A substrate 11 may include cell region A and interconnection region B around the cell region A. The substrate 11 may be a tempered glass substrate that is chemically strengthened, a reinforced plastic substrate, a polycarbonate (PC) substrate coated with a reinforcing film, and a polyethylene terephthalate (PET) substrate.

A buffer layer 13 may include a first buffer layer 13a and a second buffer layer 13b which are sequentially stacked on the substrate 11. The first buffer layer 13a may include an insulation material having a high refractive index. The first buffer layer 13a may be a transparent insulation material having a refractive index of about 1.7 to about 2.9 at a wavelength of about 550 nm. The first buffer layer 13a, for example, may include Al₂O₃, MgO, SiNₓ, ZnO, HfO₂, ZnS, TiO₂, Nb₂O₅, Ta₂O₅, SrTiO₃, or CeO₂. The first buffer layer 13a may have a thickness of about 3 nm to about 30 nm.

The second buffer layer 13b may be an insulation material having a low refractive index. The second buffer layer 13b may be a transparent insulation material having a refractive index of about 1.2 to about 1.6 at a wavelength of about 550 nm. The second buffer layer 13b, for example, may include SiO₂, SiOC, SiON, NaO₂, LaO₂, YtO₂, MgF₂, NaF, LiF, CaF₂, AlF₃, polymethyl methacrylate (PMMA), polyethylene, polypropylene, or polycarbonate. The second buffer layer 13b may have a thickness of about 10 nm to about 60 nm.

A transparent electrode 17 may be disposed on the second buffer layer 13b. The transparent electrode 17 may include X-axis electrodes 18 and Y-axis electrode cells 19a. The X-axis electrodes 18 and the Y-axis electrode cells 19a may be formed on the cell region A. A thickness of the X-axis electrodes 18 and the Y-axis electrode cells 19a may be in a range of about 100 nm to about 500 nm. The transparent electrode 17 may include an indium tin oxide (ITO) material. Here, the substrate 11 may include a first region and a second region. The first region may be a one region in which the transparent electrode 17 is not formed on one side of the substrate 11. The second buffer layer 13b may be exposed to the outside. The second region may be another region in which the transparent electrode 17 is formed on the other side of the substrate 11. The second buffer layer 13b may be covered the transparent electrode 17 on the second region.

The X-axis electrodes 18 may be formed to be aligned in a first direction (X-axis direction) on the second buffer layer 13b. The X-axis electrodes 18 may include X-axis electrode cells 18a and X-axis connection electrodes 18b. The X-axis electrode cells 18a may be formed in a diamond shape. The X-axis electrode cells 18a facing each other in a second direction (Y-axis direction) perpendicular to the first direction may be spaced apart from each other. The X-axis electrode cells 18a facing each other in the first direction may be connected by the X-axis connection electrodes 18b. However, the present invention is not limited thereto, and a pattern of the X-axis electrode cells 18a may be formed in a diamond shape, a rectangular shape, a square shape, and a polygonal shape.

The Y-axis electrode cells 19a may be formed to be aligned in the second direction (Y-axis direction) perpendicular to the first direction on the second buffer layer 13b. The X-axis connection electrodes 18b may be disposed between the Y-axis electrode cells 19a formed in the second direction. The Y-axis electrode cells 19a may be separated from the X-axis connection electrodes 18b.

Insulation patterns 21, which cover the second buffer layer 13b exposed between the X-axis connection electrodes 18b and the Y-axis electrode cells 19a, may be formed on the X-axis connection electrodes 18b. An insulation layer (not shown) is formed on the substrate 11, and the insulation patterns 21 may be formed by patterning the insulation layer. The insulation patterns 21 may cover portions of top surfaces of the Y-axis electrode cells 19a which are spaced apart from either side of the X-axis connection electrodes 18b by a predetermined distance.

Top surfaces of the insulation patterns 21 may have a convex dome shape or convex uneven shape. A thickness of the insulation patterns 21 may be changed according to the changes in the capacitance value of the touch screen panel. The insulation patterns 21 may be formed of any one material of SiOₓ, SiNₓ, MgF₂, SiOₓN_{y}, and organic materials.

Bridge electrodes 23, which connect the Y-axis electrode cells 19a spaced apart in the second direction, may be disposed on the insulation patterns 21. The bride electrodes 23 may extend to top surfaces of the Y-axis electrode cells 19a that are adjacent to each other on either side of the insulation patterns 21. Therefore, the bridge electrodes 23 may electrically connect the Y-axis electrode cells 19a that are spaced apart from each other. The bridge electrodes 23 may be a single and/or multilayered metal layer formed of any one material of molybdenum (Mo), aluminum (Al), copper (Cu), chromium (Cr), silver (Ag), titanium (Ti)/Cu, Ti/Ag, Cr/Ag, Cr/Cu, Al/Cu, and Mo/Al/Mo.

An adhesive layer 30 may be formed on the touch screen panel 10 in which the bridge electrodes 23 are formed. For example, the adhesive layer 30 may be disposed between the touch screen panel 10 and the display panel 40 to bond the touch screen panel 10 and the display panel 40 together. The touch panel 10 may be combined with the display panel 40 to constitute a display 100. The adhesive layer 30, as a transparent material, for example, may be an optically clear adhesive (OCA) film including a polymer. The display panel 40 may be a liquid crystal panel or an organic light-emitting panel. Since the adhesive layer 30 may have a refractive index similar to a refractive index of the display panel 40 including glass, the adhesive layer 30 may minimize light reflection between the touch screen panel 10 and the display panel 40.

Metal interconnections 25a and 25b may be formed in the interconnection region B of the substrate 11. The metal interconnections 25a and 25b may include driving line metal interconnections 25a that are connected to the X-axis electrodes 18 and sensing line metal interconnections 25b that are connected to the Y-axis electrode cells 19a. The metal interconnections 25a and 25b may be a single and/or multilayered metal layer formed of any one material of Mo, Al, Cu, Cr, Ag, Ti/Cu, Ti/Ag, Cr/Ag, Cr/Cu, Al/Cu, and Mo/Al/Mo. A voltage may be applied to the transparent electrode 17 through the metal interconnections 25a and 25b.

The X-axis electrode cells 18a, which are arranged in the second direction, and the Y-axis electrode cells are respectively spaced apart from one another. Therefore, a portion of the second buffer layer 13b may be exposed. For example, referring to FIG. 2C, the second buffer layer 13b may be exposed by the X-axis electrode cells 18a. A difference between a transmittance T1 of light transmitted through the X-axis electrode cells 18a and a transmittance T2 of light transmitted through the exposed second buffer layer 13b is denoted as index matching. In the case that the index matching is about 1.5% or less, the first region and the second region may not be visually differentiated.

In general, in order to realize a touch screen panel having a size of 20 inches or more, an ITO layer used as a transparent electrode must be thick at about 100 nm or more to reduce its electrical resistance. However, in the case that the ITO layer is about 100 nm or more, a large-sized touch screen panel may be difficult to be realized because the transmittance and index matching characteristics of the touch screen panel degrade. In the present embodiment, a touch screen panel having an index matching of about 1.5% or less and a transmittance of about 85% may be realized by providing the transparent electrode 17 having a thickness of about 100 nm or more and controlling materials and thicknesses of the first and second buffer layers 13a and 13b. Therefore, a large-sized touch screen panel having a size of 20 inches or more may be commercialized.

Referring to FIG. 3, a graph illustrates the results of an index matching simulation of a touch screen panel according to a thickness of a transparent electrode. A glass substrate was used as a substrate. Nb₂O₅ and SiO₂ were respectively used as a high refractive index buffer layer and a low refractive index buffer layer. ITO was used as the transparent electrode and an OCA layer was formed on the transparent electrode. An extinction coefficient (k) of the transparent electrode in a visible region was assumed as 0.

As illustrated in FIG. 3, points indicated in the graph denote the results in which an index matching ratio satisfies about 1% or less in the total visible region while the thickness of each buffer layer is changed with respect to the thickness of the ITO layer provided.

As a result, it may be understood that conditions, which may satisfy an index matching of about 1% or less as well as a transmittance of about 90% or more with respect to the ITO layer having a thickness ranging from about 100 nm to about 500 nm, are discontinuous, but apparently exist. A range in which the graph is disconnected means that conditions satisfying an index matching of within about 1% do not exist in the range. As a result, an index matching ratio of about 1% or less and a transmittance of about 90% or more may be obtained at an ITO thickness of about 100 nm to about 200 nm, about 270 nm to about 305 nm, about 335 nm to about 350 nm, 395 nm, and about 470 nm to about 495 nm. However, the present invention is not limited thereto, and the index matching ratio may be about 1.5% or less and the transmittance may be about 85% or more. That is, it may be understood that a touch screen panel having excellent index matching and transmittance may be realized in the case in which an OCA layer is used even if a thick ITO layer is used.

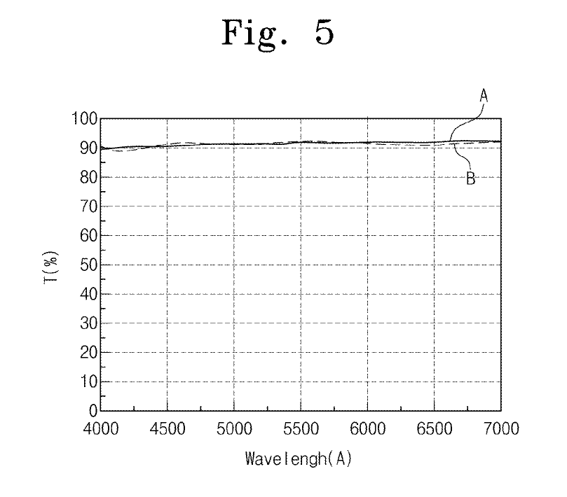

FIG. 4 is a graph illustrating a transmittance of a touch screen panel according to an embodiment of the inventive concept when a thickness of ITO is about 120 nm. FIG. 5 is a graph illustrating a transmittance of the touch screen panel according to the embodiment of the inventive concept when the thickness of the ITO is about 395 nm.

A glass substrate was used as a substrate. Nb₂O₅ and SiO₂ were respectively used as a high refractive index buffer layer and a low refractive index buffer layer. ITO was used as the transparent electrode and an OCA layer was formed on the transparent electrode. In FIG. 4, thicknesses of the Nb₂O₅ and SiO₂ were respectively about 8 nm and about 36 nm, and in FIG. 5, the thicknesses of the Nb₂O₅ and SiO₂ were respectively about 11.5 nm and about 31.5 nm. Solid line A denotes a transmittance of light transmitted through a region without the transparent electrode and dotted line B denotes a transmittance of light transmitted through a region with the transparent electrode.

As illustrated in FIGS. 4 and 5, a transmittance of 90% or more may be confirmed in the case that the thicknesses of the transparent electrode were respectively about 120 nm and about 395 nm, and it may be confirmed that the transmittance B of the region with the transparent electrode and the transmittance A of the region without the transparent electrode were almost coincided. That is, it may be confirmed that a touch screen panel having an index matching of about 1% or less may be realized even if an ITO layer having a thickness of about 100 nm or more was used. The reason for the realization of an index matching of about 1% or less even in the case of the thick ITO layer is related to the use of OCA. In the case that the OCA is not used, i.e., the transparent electrode is directly in contact with air, it may be confirmed from an optical simulation that the transmittance and index matching characteristics significantly degrade due to the drastic difference in the refractive index with respect to air (not shown).

Table 1 illustrates thickness ranges of buffer layers satisfying an index matching of about 1% or less that were obtained from simulations performed on various buffer layer materials when a thickness range of ITO was about 100 nm to about 500 nm. Herein, it was also assumed that an OCA layer was used. As listed in Table 1, when the thickness range of the ITO was about 100 nm to about 500 nm, it may be understood that the thickness range of high refractive index materials satisfying the index matching was about 5 nm to about 23 nm, and the thickness range of low refractive index materials was about 16 nm to about 45 nm.

TABLE 1

| | | Thickness | Thickness | | |
|---|---|---|---|---|---|
| | | range of | range of | Mini- | Maxi- |
| | | first | second | mum | mum |
| | Thickness | buffer | buffer | trans- | trans- |
| Buffer layer | range | layer | layer | mittance | mittance |
| combination | of ITO | (nm) | (nm) | (%) | (%) |
| ZnO/SiO₂ | 100 to 295 | 11 to 23 | 16 to 43 | 90.4 | 92.5 |
| TiO₂/SiO₂ | 100 to 295 | 5 to 11 | 21 to 45 | 90.3 | 92.4 |
| Nb₂O₅/SiO₂ | 100 to 495 | 7 to 13 | 21 to 45 | 90.0 | 92.3 |
| Nb₂O₅/MgF₂ | 100 to 495 | 9 to 15 | 18 to 36 | 90.1 | 92.3 |

According to the results of the above-described simulations, even in the case in which the ITO had a large thickness of about 100 nm to about 495 nm, a high transmittance of about 90% or more may be obtained in the region having the ITO formed therein by controlling the materials and thicknesses of the first and second buffer layers 13a and 13b.

A touch screen panel according to an embodiment of the inventive concept uses an ITO transparent electrode having a thickness of about 100 nm to about 500 nm and thus, may realize a difference in transmittance between a region having the transparent electrode formed therein and a region not having the transparent electrode formed therein of about 1.5% or less.

Therefore, a large-area touch screen panel having a size of 20 inches or more may be realized.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A touch screen panel comprising:
a transparent substrate including a first region and a second region;
a buffer layer disposed on the first region and second region, the buffer layer having a first transmittances; and
a transparent indium tin oxide (ITO) electrode disposed on the buffer layer of the second region, the transparent ITO electrode and the buffer layer on the second region having a second transmittance,
wherein a thickness of the transparent ITO electrode is 100 nm to 500 nm, and
a difference between the first transmittance and the second transmittance is less than 1.5%.

2. The touch screen panel of claim 1, wherein the first transmittance is 85% or more.

3. The touch screen panel of claim 1, wherein the buffer layer comprises a high refractive index buffer layer on the substrate and a low refractive index buffer layer on the high refractive index buffer layer.

4. The touch screen panel of claim 3, wherein the high refractive index buffer layer comprises Al₂O₃, MgO, SiNₓ, ZnO, HfO₂, ZnS, TiO₂, Nb₂O₅, Ta₂O₅, SrTiO₃, or CeO₂.

5. The touch screen panel of claim 4, wherein a thickness of the high refractive index buffer layer is 3 nm to 30 nm.

6. The touch screen panel of claim 3, wherein the low refractive index buffer layer comprises SiO₂, SiOC, SiON, NaO₂, LaO₂, YtO₂, MgF₂, NaF, LiF, CaF₂, AlF₃, polymethyl methacrylate (PMMA), polyethylene, polypropylene, or polycarbonate.

7. The touch screen panel of claim 6, wherein a thickness of the low refractive index buffer layer is in a range of 10 nm to 60 nm.

8. The touch screen panel of claim 1, wherein the transparent ITO electrode comprises:
X-axis electrodes which include X-axis electrode cells aligned in a first direction and X-axis connection electrodes connecting the X-axis electrode cells; and
Y-axis electrode cells which are spaced apart from the X-axis electrodes and are disposed adjacent to the X-axis connection electrodes in a Y-axis direction.

9. The touch screen panel of claim 8, further comprising:
insulation patterns which cover the X-axis connection electrodes disposed between the Y-axis electrode cells; and
bridge electrodes which are disposed on the insulation patterns and connect the Y-axis electrode cells.

10. A display comprising:
a touch panel;
an adhesive layer on the touch panel; and
a display panel disposed on the adhesive layer,
wherein the touch panel comprises:
a transparent substrate including a first region and a second region;
a buffer layer disposed on the first region and second region, the buffer layer having a first transmittances; and
a transparent indium tin oxide (ITO) electrode disposed on the buffer layer of the second region, the transparent ITO electrode and the buffer layer on the second region having a second transmittance,
wherein a thickness of the transparent ITO electrode is 100 nm to 500 nm, and
a difference between the first transmittance and the second transmittance is less than 1.5%.

11. The display of claim 10, wherein the adhesive layer is an optically clear adhesive (OCA) film comprising a polymer.

12. The display of claim 11, wherein the display panel comprises a liquid crystal panel or an organic light-emitting panel.
